(19) United States
(12) Patent Application Publication
(10) Pub. No.: US 2009/0133784 A1
(43) Pub. Date: May 28, 2009

(54) COPPER ALLOY THIN FILMS, COPPER ALLOY SPUTTERING TARGETS AND FLAT PANEL DISPLAYS

(75) Inventors: Toshihiro KUGIMIYA, Kobe-shi (JP); Katsufumi TOMIHISA, Kobe-shi (JP); Katsutoshi TAKAGI, Kobe-shi (JP); Junichi NAKAI, Kobe-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Kobe Seiko Sho (Kobe Steel, Ltd.), Kobe-shi (JP)

(21) Appl. No.: 12/355,274

(22) Filed: Jan. 16, 2009

Related U.S. Application Data
(62) Division of application No. 11/235,196, filed on Sep. 27, 2005.

(30) Foreign Application Priority Data
Nov. 2, 2004 (JP) 2004-319644

(51) Int. Cl. C22C 9/00; B32B 15/00; C23C 14/34

(52) U.S. Cl. 148/432; 428/457; 204/192.15

(57) ABSTRACT

A Cu alloy thin film contains Fe and P with the balance being substantially Cu, in which the contents of Fe and P satisfy all the following conditions (1) to (3), and in which Fe₂P is precipitated at grain boundaries of Cu after heat treatment at 200° C. to 500° C. for 1 to 120 minutes:

1.4N_{Fe}+8N_{P}<1.3 (1)

N_{Fe}+48N_{P}>1.0 (2)

12N_{Fe}+N_{P}>0.5 (3)

wherein N_{Fe} represents the content of Fe (atomic percent); and N_{P} represents the content of P (atomic percent).

### BACKGROUND OF THE INVENTION

1. Field of the Invention

The present invention relates to Cu alloy thin films, Cu alloy sputtering targets and flat panel displays. Specifically, it relates to Cu alloy thin films that are reduced in voids while keeping their low electrical resistivities even after heat treatment; sputtering targets for the deposition of the Cu alloy thin films; and flat panel displays using the Cu alloy thin films as an interconnection film and/or electrode film.

2. Description of the Related Art

Flat panel displays typified by liquid crystal displays, plasma display panels, field emission displays, and electroluminescence displays have been upsized. To reduce signal delay in signal lines with increasing sizes of the displays, materials having lower electrical resistivities must be used in interconnections in the flat panel displays. Among the displays, liquid crystal displays further require lower electrical resistivity in their interconnections for driving pixels, such as gate lines and source-drain lines of thin film transistors (TFTs). Al alloys having thermostability, such as Al—Nd, are now used as materials for their interconnections.

Ag and Cu having lower electrical resistivities than pure Al (resistivity of less than 3.3 μΩ·cm: experimental value in thin film) receive attention as materials for interconnections for liquid crystal displays, since the liquid crystal displays typified by displays for liquid crystal televisions have been upsized to 40 inches diagonally or more, and the signal delay accompanied with upsizing must be avoided. Upon application to liquid crystal displays, Ag, however, is poor in adhesion with glass substrates and/or SiN dielectric films, is not sufficiently processed into interconnections by wet etching and causes insulation failure due to the cohesion of the Ag element. In contrast, Cu has been used in LSIs and is more practically applicable than Ag to liquid crystal displays. In fact, display panels and liquid crystal devices using Cu as a material for interconnections have been proposed (e.g., Japanese Patent Application Laid-Open (JP-A) No. 2002-202519; And Japanese Patent Application Laid-Open (JP-A) No. 10-253976).

Such Cu materials for interconnections, however, must be improved in some points. One of them is inhibition of intergranular fractures called voids. Processes for fabricating interconnections for TFTs in liquid crystal displays (hereinafter referred to as “liquid crystal TFT”) include a heat treatment process, in which a work is heated to about 300° C. after deposition of thin film by sputtering in the fabrication of a gate insulation film or an interlayer dielectric film. During temperature fall in the heat treatment process, the resulting metal interconnections (Cu interconnections) experiences tensile stress caused by the difference in coefficient of thermal expansion between the glass substrate and the metal interconnections. The tensile stress causes fine fractures called voids at grain boundaries in the metal interconnections, which in turn reduces the reliability of the interconnections, such as resistance to break caused by stress migration (SM resistance) or resistance to break caused by electromigration (EM resistance).

In contrast to Al, Cu has significantly varying Young's modulus and modulus of rigidity depending on crystal orientation. Thus, polycrystalline Cu interconnections suffer very large strain between different crystal orientations upon temperature fall after the heat treatment, which frequently causes grain boundary delamination (voids or cracks).

In addition, Cu is susceptible to oxidation, and internal oxidation and grain boundary delamination (voids or cracks) accompanied with this must be inhibited when Cu is used as a material for interconnections. The grain boundaries include a large quantity of crystal defects of atomic vacancy, called “vacancy”, and this causes acceleration of oxidation. When the grain boundaries are oxidized to form CuOₓ, the CuOₓ is corroded in a rinsing process in the fabrication, and voids or cracks form along with the grain boundaries to thereby increase the electrical resistance of the Cu interconnections. In addition to the increased electrical resistance, the internal oxidation with grain boundary delamination significantly adversely affects the reliability of the interconnections, since it causes, for example, break of the interconnections.

### SUMMARY OF THE INVENTION

Under these circumstances, an object of the present invention is to provide a Cu alloy thin film that can maintain a lower electrical resistivity than pure Al and inhibit void formation even after exposure to high temperatures in a fabrication process typically of flat panel displays. Another object of the present invention is to provide a sputtering target for depositing the Cu alloy thin film, and a flat panel display using the Cu alloy thin film as an interconnection film and/or electrode film.

Specifically, the present invention provides:

(a) a Cu alloy thin film containing Fe and P with the balance being substantially Cu, wherein the contents of Fe and P satisfy all the following conditions (1) to (3):

1.4N_{Fe}+8N_{P}<1.3 (1)

N_{Fe}+48N_{P}>1.0 (2)

12N_{Fe}+N_{P}>0.5 (3)

wherein N_{Fe} represents the content of Fe (atomic percent); and N_{P} represents the content of P (atomic percent);

(b) a Cu alloy thin film containing Co and P with the balance being substantially Cu, wherein the contents of Co and P satisfy all the following conditions (4) to (6):

1.3N_{Co}+8N_{P}<1.3 (4)

N_{Co}+73N_{P}>1.5 (5)

12N_{Co}+N_{P}>0.5 (6)

wherein N_{Co} represents the content of Co (atomic percent); and N_{P} represents the content of P (atomic percent); and

(c) a Cu alloy thin film containing Mg and P with the balance being substantially Cu, wherein the contents of Mg and P satisfy all the following conditions (7) to (9):

0.67N_{Mg}+8N_{P}<1.3 (7)

2N_{Mg}+197N_{P}>4 (8)

16N_{Mg}+N_{P}>0.5 (9)

wherein N_{Mg} represents the content of Mg (atomic percent); and N_{P} represents the content of P (atomic percent).

The Cu alloy thin films are most suitable as interconnection films and/or electrode films for flat panel displays. Even after heat treatment at 200° C. to 500° C. for 1 to 120 minutes, Fe₂P, Co₂P, and Mg₃P₂ are precipitated at grain boundaries in the Cu alloy thin films (a), (b) and (c), respectively, to serve to maintain their low electrical resistivities and inhibit the formation of voids.

The present invention also includes sputtering targets for the deposition of these Cu alloy thin films. Specifically, the Cu alloy thin film (a) may be deposited by using a sputtering target containing Fe and P with the balance being substantially Cu, wherein the contents of Fe and P satisfy all the following conditions (10) to (12):

1.4N_{Fe}+1.6N_{P}′<1.3 (10)

N_{Fe}+9.6N_{P}′>1.0 (11)

12N_{Fe}+0.2N_{P}′>0.5 (12)

wherein N_{Fe} represents the content of Fe (atomic percent); and N_{P}′ represents the content of P (atomic percent).

The Cu alloy thin film (b) may be deposited by using a sputtering target containing Co and P with the balance being substantially Cu, wherein the contents of Co and P satisfy all the following conditions (13) to (15):

1.3N_{Co}+1.6N_{P}′<1.3 (13)

N_{Co}+14.6N_{P}′>1.5 (14)

12N_{Co}+0.2N_{P}′>0.5 (15)

wherein N_{Co} represents the content of Co (atomic percent); and N_{P}′ represents the content of P (atomic percent).

The Cu alloy thin film (c) may be deposited by using a sputtering target containing Mg and P with the balance being substantially Cu, wherein the contents of Mg and P satisfy all the following conditions (16) to (18):

0.67N_{Mg}+1.6N_{P}′<1.3 (16)

2N_{Mg}+39.4N_{P}′>4 (17)

16N_{Mg}+0.2N_{P}′>0.5 (18)

wherein N_{Mg} represents the content of Mg (atomic percent); and N_{P}′ represents the content of P (atomic percent).

The present invention also includes flat panel displays each containing any of the above Cu alloy thin films as at least one of interconnection films and electrode films.

The Cu alloy thin films according to the present invention can yield Cu alloy interconnection films that maintain lower electrical resistivities than pure Al thin film and have satisfactory reliability without causing a large number of voids, even after being subjected to heat treatment at 200° C. or higher for the deposition of a gate insulator film and/or an interlayer dielectric film. The resulting interconnection films and/or electrode films are used for upsized flat panel displays such as liquid crystal displays, plasma display panels, field emission displays and electroluminescence displays.

Further objects, features and advantages of the present invention will become apparent from the following description of the preferred embodiments with reference to the attached drawings.

### BRIEF DESCRIPTION OF THE DRAWINGS

FIG. 1 is graph showing the relation of the void density after heat treatment with the amount of P in Cu—P alloy thin films;

FIG. 2 is a scanning electron microscopic (SEM) image of a Cu-0.1 atomic percent P alloy thin film after vacuum heat treatment at 300° C.;

FIG. 3 is a graph showing the relation of the electrical resistivity with the amount of P in Cu—P alloy thin films;

FIG. 4 is a graph showing the relation of the void density after heat treatment with the amount of Fe in Cu—Fe alloy thin films;

FIG. 5 is a scanning electron microscopic (SEM) image of a Cu-0.28 atomic percent Fe alloy thin film after vacuum heat treatment at 300° C.;

FIG. 6 is a graph showing the relation of the electrical resistivity with the amount of Fe in Cu—Fe alloy thin films;

FIG. 7 is a graph showing the relation of the electrical resistivity with the heat treatment temperature in Cu—P alloy thin films and Cu—Fe—P alloy thin films;

FIG. 8 is a graph showing the relation of the amounts of Fe and P with the void density after heat treatment in Cu—Fe—P alloy thin films;

FIG. 9 is a graph showing the relation of the amounts of Co and P with the void density after heat treatment in Cu—Co—P alloy thin films;

FIG. 10 is a graph showing the relation of the amounts of Mg and P with the void density after heat treatment in Cu—Mg—P alloy thin films; and

FIG. 11 is a scanning electron microscopic (SEM) image of a Cu-0.28 atomic percent Fe-0.05 atomic percent P alloy thin film after heat vacuum treatment at 300° C.

### DESCRIPTION OF THE PREFERRED EMBODIMENTS

The present inventors made intensive investigations on Cu alloy thin films that can maintain lower electrical resistivities than pure Al thin film and markedly reduce “voids” even exposure to elevated temperatures of 200° C. or higher in the fabrication process of liquid crystal TFTs. Such voids occur in the fabrication of interconnection films using pure Cu thin films. They also made intensive investigations on compositions of sputtering targets for the deposition of the Cu alloy thin films.

Consequently, they found that Cu-based thin films containing P and at least one selected from Fe, Co and Mg can maintain their low electrical resistivities and inhibit voids more significantly than in pure Cu thin film. After further investigations, they have found controlling the ratio of P to Fe, Co or Mg in Cu alloys is effective to reliably exhibit these operation and advantages. The present invention has been achieved based on these findings. The details leading to the present invention will be described below.

Initially, the present inventors considered that P is useful for inhibiting internal oxidation by trapping oxygen contained as impurities in a Cu thin film and made investigations on the relation of the content of P with the amount of voids occurred after heat treatment in Cu-based thin films containing P, i.e., Cu—P alloy thin films.

Specifically, a series of Cu—P alloy thin films or pure Cu thin film containing 0 to 0.5 atomic percent of P and having a film thickness of 300 nm was deposited on a glass substrate (#1737 glass available from Corning Inc.) using a sputtering apparatus. A pattern of interconnections with a line width of 10 μm was fabricated thereon by photolithography and wet etching with a mixed acid etchant (mixed acid containing sulfuric acid, nitric acid, and acetic acid), followed by vacuum heat treatment at 300° C. for 30 minutes. Voids observed on the surface of the pattern of interconnections were counted to determined a void density. The above heat treatment was carried out in consideration that the heat treatment temperature in its hysteresis in the fabrication of liquid crystal TFTs generally attains maximum at 350° C. in a fabrication process of a gate insulation film and at 300° C. in a fabrication process of a source-drain interconnection film.

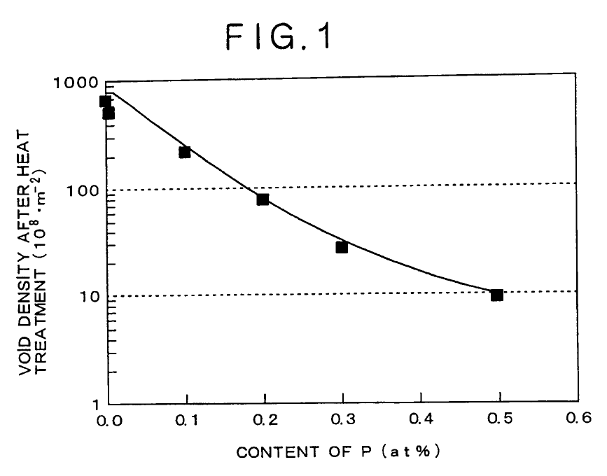

The experiment results are shown in FIG. 1 as the relation of the void density after heat treatment with the amount of P in Cu—P alloy thin films. FIG. 1 demonstrates that the void density decrease with an increasing amount of P, and that P should be added in an amount of 0.2 atomic percent or more for controlling the void density to 1.0×10¹⁰ m⁻² or less, which is a practically acceptable level.

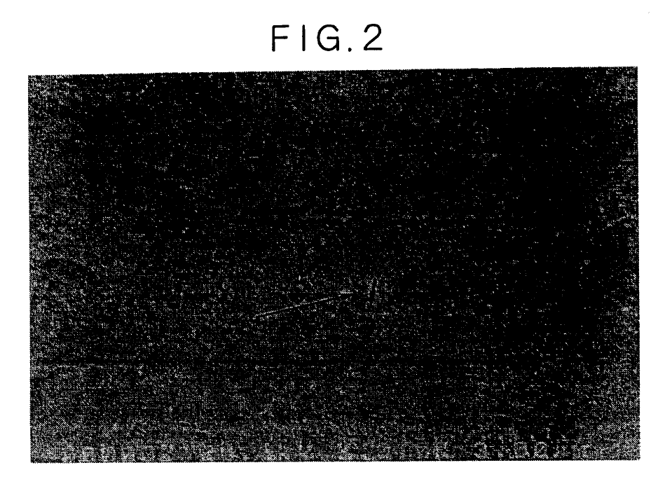

For reference, FIG. 2 shows a scanning electron microscopic (SEM) image of a Cu-0.1 atomic percent P alloy thin film after vacuum heat treatment at 300° C. Herein, the Cu alloy thin film was deposited, was subjected to photolithography and wet etching with a mixed acid etchant to form a pattern of interconnections with a line width of 10 μm and was subjected to vacuum heat treatment at 300° C. for 30 minutes. FIG. 2 shows a photograph in which the surface of the pattern of interconnections was etched with a mixed acid etchant for easy identification of grain boundaries after heat treatment. The black area indicated by the arrow in FIG. 2 is a void.

The present inventors also made investigations on effects of the amount of P on electrical resistivity in Cu—P alloy thin films. Specifically, a series of Cu—P alloy thin films having a P content of 0.03 atomic percent or 0.09 atomic percent and having a film thickness of 300 nm was deposited on a glass substrate (#1737 glass available from Corning Inc.) using a sputtering apparatus and was subjected to vacuum heat treatment at 300° C. for 30 minutes. The electrical resistivities of the Cu—P alloy thin films after the heat treatment were determined. This heat treatment was carried out also in consideration of the hysteresis of the heat treatment temperature in the fabrication of liquid crystal TFTs. Separately, a pure Cu thin film to which P was not added was deposited, was subjected to the heat treatment, and its electrical resistivity was determined.

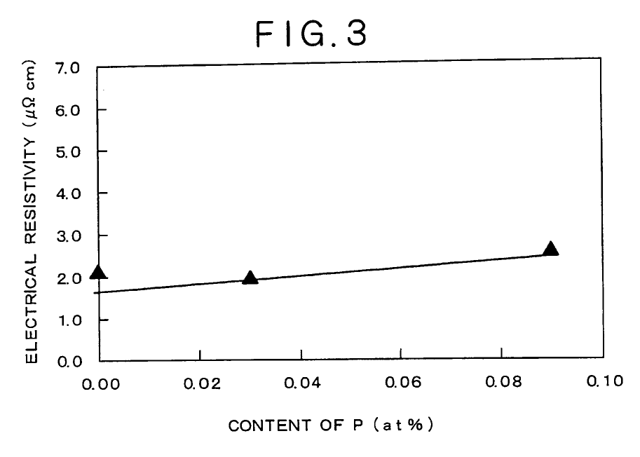

These experiment results are shown in FIG. 3 as the relation of the electrical resistivity with the amount of P in Cu—P alloy thin films. FIG. 3 demonstrates that the addition of 0.1 atomic percent of P increases the electrical resistivity 0.8 μΩ·cm as compared with that of the pure Cu thin film.

The pure Al thin film was found to have an electrical resistivity of 3.3 μΩ·cm after heat treatment as a result of a similar experiment as above. FIG. 3 shows that the P amount must be 0.16 atomic percent or less (inclusive of 0 atomic percent) to yield a Cu—P alloy thin film having an electrical resistivity lower than that of the pure Al thin film.

These experimental results on Cu—P alloy thin films demonstrate that the amount of P must be 0.2 atomic percent or more to inhibit voids caused by heat treatment, but it must be 0.16 atomic percent or less (inclusive of 0 atomic percent) to achieve an electrical resistivity lower than that of the pure Al thin film, and that control of the amount of P in Cu—P alloy thin films does not simultaneously contribute to reduction of electrical resistivity and the inhibition of voids.

Next, the present inventors fabricated Cu-based alloy thin films containing Fe, i.e., Cu—Fe alloy thin films, to verify the relation of the amount of Fe with the void formation. Fe is considered to be useful for strengthening grain boundaries, since Fe is precipitated at grain boundaries.

Specifically, a series of Cu—Fe alloy thin films having an Fe content of 0 to 1.0 atomic percent and having a film thickness of 300 nm was deposited on a glass substrate (#1737 glass available from Corning Inc.) using a sputtering apparatus. The thin films were subjected to photolithography and wet etching with a mixed acid etchant to fabricate a pattern of interconnections with a line width of 10 nm and were subjected to vacuum heat treatment at 300° C. for 30 minutes. The voids observed on the surface of the pattern of interconnections were counted to determine the void density. The above heat treatment was carried out in consideration that the heat treatment temperature in its hysteresis in the fabrication of liquid crystal TFTs generally attains maximum at 350° C. in a fabrication process of a gate insulator film and at 300° C. in a fabrication process of a source-drain interconnection film.

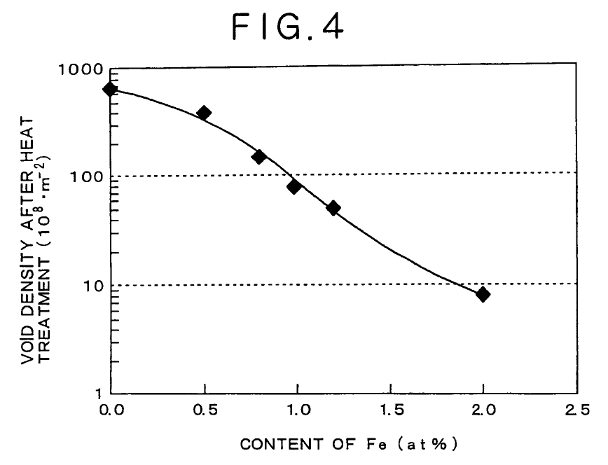

The experimental results are shown in FIG. 4 as the relation of the void density after heat treatment with the amount of Fe in Cu—Fe alloy thin films. FIG. 4 demonstrates that the void density decreases with an increasing amount of Fe, and that the Fe amount should preferably be 1.0 atomic percent or more to achieve a practically acceptable void density of 1.0×10¹⁰ m⁻² or less.

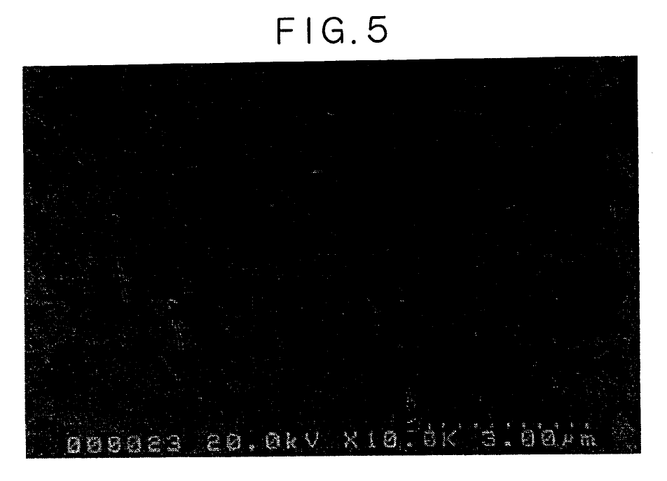

For reference, FIG. 5 shows a scanning electron microscopic (SEM) image of a Cu-0.28 atomic percent Fe alloy thin film after vacuum heat treatment at 300° C. Herein, the Cu alloy thin film was deposited, was subjected to photolithography and wet etching with a mixed acid etchant to form a pattern of interconnections with a line width of 10 μm and was subjected to vacuum heat treatment at 300° C. for 30 minutes, as in FIG. 2. FIG. 5 shows a photograph in which the surface of the pattern of interconnections was etched with a mixed acid etchant for easy identification of grain boundaries after heat treatment. The black areas indicated by the arrow in FIG. 5 are voids. FIG. 5 shows that a large quantity of voids occur when Fe is added in a small amount of 0.28 atomic percent.

The present inventors also made investigations on relation of the amount of Fe with electrical resistivity in Cu—Fe alloy thin films. Specifically, a series of Cu—Fe alloy thin films having a Fe content of 0.3 atomic percent or 0.9 atomic percent and having a film thickness of 300 nm was deposited on a glass substrate (#1737 glass available from Corning Inc.) using a sputtering apparatus and was subjected to vacuum heat treatment at 300° C. for 30 minutes. The electrical resistivities of the Cu—Fe alloy thin films after the heat treatment were determined. This heat treatment was carried out also in consideration of the hysteresis of the heat treatment temperature in the fabrication of liquid crystal TFTs. Separately, a pure Cu thin film to which Fe was not added was deposited, was subjected to the heat treatment, and its electrical resistivity was determined.

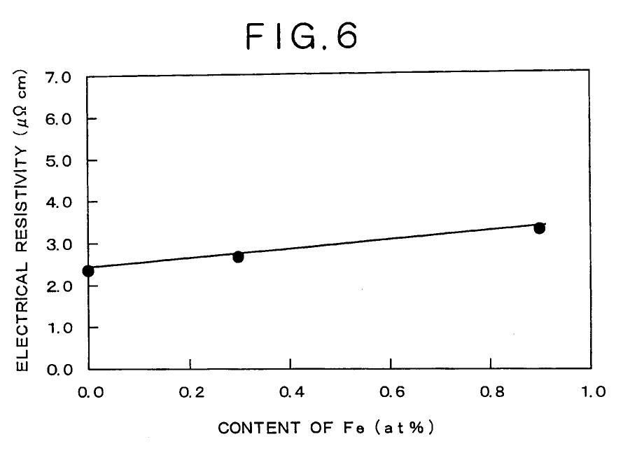

These experimental results are shown in FIG. 6 as the relation of the electrical resistivity with the amount of Fe in Cu—Fe alloy thin films. FIG. 6 demonstrates that the addition of 0.1 atomic percent of Fe increases the electrical resistivity 0.14 μΩ·cm as compared with that of the pure Cu thin film. FIG. 6 also demonstrates that the amount of Fe must be controlled to 0.93 atomic percent or less (inclusive of 0 atomic percent) to yield a Cu—Fe alloy thin film having an electrical resistivity lower than that of the pure Al thin film.

These experimental results on Cu—Fe alloy thin films demonstrate that the amount of Fe must be 1.0 atomic percent or more to inhibit voids caused by heat treatment, but it must be 0.93 atomic percent or less (inclusive of 0 atomic percent) to achieve an electrical resistivity lower than that of the pure Al thin film, and that control of the amount of Fe in Cu—Fe alloy thin films does not simultaneously contribute to reduction of electrical resistivity and inhibition of voids.

Next, the present inventors made investigations on effects of the addition of Fe and P in combination to pure Cu. Initially, a series of Cu—P—Fe alloy thin films containing a constant amount of P and a varying amount of Fe were deposited and subjected to vacuum heat treatment at varying temperatures to make investigations on effects of the heat treatment temperature and the amount of Fe on electrical resistivity of Cu—P—Fe alloy thin films after heat treatment.

Specifically, a series of Cu—Fe—P alloy thin films having a constant amount of P, 0.1 atomic percent, and a varying amount of Fe, 0 to 0.5 atomic percent, and having a film thickness of 300 nm was deposited on a glass substrate (#1737 glass available from Corning Inc.) using a sputtering apparatus. The thin films were then subjected to vacuum heat treatment while holding at different temperatures of 200° C. to 500° C. for 30 minutes, respectively. The electrical resistivities of the Cu—Fe—P alloy thin films after the heat treatment were determined.

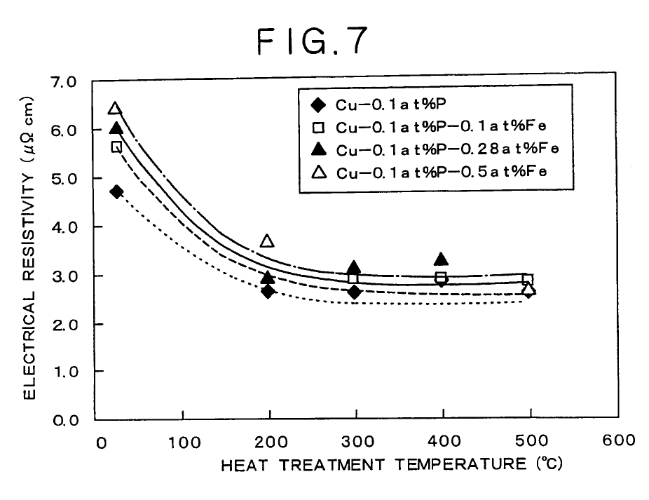

The results are shown in FIG. 7 as the relations of the heat treatment temperature and the amount of Fe with the electrical resistivity. FIG. 7 demonstrates that heat treatments at a temperature of 200° C. or higher achieve substantially constant low electrical resistivities, independent on the amount of Fe.

The increase in electrical resistivity caused by the addition of Fe and P to pure Cu must be less than 1.3 μΩ·cm, since the difference in electrical resistivities between the pure Al thin film and the pure Cu thin film is 1.3 μΩ·cm. The increase ratio of electrical resistivities as a coefficient is determined from the results in FIGS. 3 and 6 to yield following condition (1), wherein N_{Fe} represents the content of Fe (atomic percent); and N_{P} represents the content of P (atomic percent) in Cu alloy thin films. Controlling the amounts of Fe and P in Cu alloy thin films so as to satisfy following condition (1) achieves an electrical resistivity lower than that of the pure Al thin film.

1.4N_{Fe}+8N_{P}<1.3 (1)

Next, the relations of the amounts of Fe and P with the density of voids occurred after heat treatment in the Cu—Fe—P alloy thin films were investigated. In the experiment, the Cu—Fe—P alloy thin films were deposited and were subjected to photolithography and wet etching with a mixed acid etchant to thereby fabricate a pattern of interconnections having a line width of 10 μm , followed by vacuum heat treatment at 300° C. for 30 minutes. The voids fabricated in the pattern of interconnections having a line width of 10 μm were counted to determine the void density. A sample thin film having a void density at a practically acceptable level, 1.0×10¹⁰ m⁻² or less, was evaluated as “Passed” (represented by “O” in the drawing) and one having a void density exceeding 1.0×10¹⁰ m⁻² was evaluated as “Failed” (represented by “X” in the drawing).

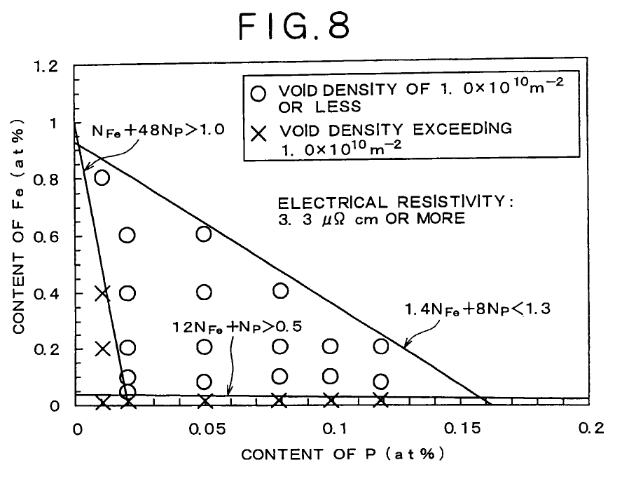

The results are shown in FIG. 8 as the relations of the amounts of Fe and P with the void density after heat treatment in Cu—Fe—P alloy thin films. FIG. 8 demonstrates that void formation can be inhibited by setting the amounts of Fe and P in Cu—Fe—P alloy thin film so as to satisfy following conditions (2) and (3):

N_{Fe}+48N_{P}>1.0 (2)

12N_{Fe}+N_{P}>0.5 (3)

In addition, the results demonstrate that controlling the amounts of Fe and P in Cu—Fe—P alloy thin films to satisfy all following conditions (2) and (3) in combination with Condition (1) necessary for ensuring low electrical resistivities achieves both low electrical resistivities and void inhibition, as is illustrated in FIG. 8.

1.4N_{Fe}+8N_{P}<1.3 (1)

N_{Fe}+48N_{P}>1.0 (2)

12N_{Fe}+N_{P}>0.5 (3)

Single addition of Fe or P to Cu does not simultaneously achieve these advantages “electrical resistivity lower than that of pure Al thin film ” and “inhibition of voids”. The reason why “electrical resistivity lower than that of pure Al thin film” and “inhibition of voids” can be simultaneously achieved by the combination addition of appropriate amounts of Fe and P to Cu has not yet been sufficiently clarified. This is probably because a fine intermetallic compound Fe₂P is precipitated at grain boundaries of Cu as a result of heat treatment of Cu—Fe—P alloy thin films at 200° C. or higher, strengthens the grain boundary and thereby inhibits void formation due to heat stress (tensile stress). The low electrical resistivity is maintained probably because the intermetallic compound is precipitated not in the Cu grains but at grain boundaries thereof.

The present inventors made further investigations on other elements than Fe which form P compounds and found that Co and Mg exhibit similar effects, and that the combination addition of two or more elements selected from the group consisting of Fe, Co and Mg exhibits similar effects. Cu alloy thin films containing P in combination with Co or Mg will be described in detail below.

Initially, a series of Cu—Co—P alloy thin films containing varying amounts of Co and P was deposited, the electrical resistivities of the resulting thin films were determined, and the relations of the amounts of Co and P with the electrical resistivity in Cu—Co—P alloy thin films were determined in the same manner as in FIG. 8. The results demonstrate that electrical resistivities lower than that of the pure Al thin film can be ensured by setting the amounts of Co and P in the Cu—Co—P alloy thin films so as to satisfy following condition (4).

1.3N_{Co}+8N_{P}<1.3 (4)

In addition, the relations of the amounts of Co and P with the density of voids occurred after heat treatment in the Cu—Co—P alloy thin films were investigated. In the experiment, the Cu—Co—P alloy thin films were deposited and were subjected to photolithography and wet etching with a mixed acid etchant to thereby fabricate a pattern of interconnections having a line width of 10 μm, followed by vacuum heat treatment at 300° C. for 30 minutes. The voids fabricated in the pattern of interconnections having a line width of 10 μm were counted to determine the void density. A sample thin film having a void density at a practically acceptable level, 1.0×10¹⁰ m⁻² or less, was evaluated as “Passed” (represented by “O” in the drawing) and one having a void density exceeding 1.0×10¹⁰ m⁻² was evaluated as “Failed” (represented by “X” in the drawing).

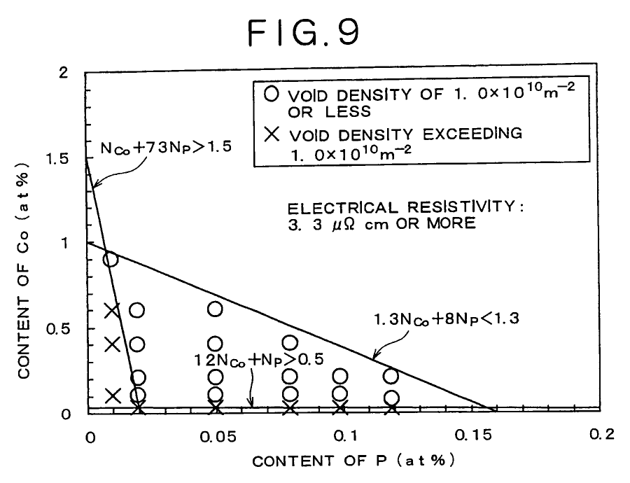

The results are shown in FIG. 9 as the relations of the amounts of Co and P with the void density after heat treatment in Cu—Co—P alloy thin films. FIG. 9 demonstrates that void formation can be inhibited by setting the amounts of Co and P in Cu—Co—P alloy thin film so as to satisfy following conditions (5) and (6):

N_{Co}+73N_{P}>1.5 (5)

12N_{Co}+N_{P}>0.5 (6)

In addition, the results demonstrate that controlling the amounts of Co and P in Cu—Co—P alloy thin films to satisfy following conditions (5) and (6) in combination with condition (4) necessary for ensuring low electrical resistivities achieves both low electrical resistivities and void inhibition, as is illustrated in FIG. 9. In this case, also, precipitation of Co₂P at grain boundaries probably achieves low electrical resistivities and inhibition of voids simultaneously.

1.3N_{Co}+8N_{P}<1.3 (4)

N_{Co}+73N_{P}>1.5 (5)

12N_{Co}+N_{P}>0.5 (6)

Next, the present inventors made investigations on Cu—Mg—P alloy thin films containing Mg instead of Fe or Co. Initially, a series of Cu—Mg—P alloy thin films containing varying amounts of Mg and P was deposited, the electrical resistivities of the thin films were determined, and the relations of the amounts of Mg and P with the electrical resistivity in Cu—Mg—P alloy thin films were determined, as in FIGS. 8 and 9. The results demonstrate that electrical resistivities lower than that of the pure Al thin film can be ensured by setting the amounts of Mg and P in the Cu—Mg—P alloy thin films so as to satisfy following condition (7):

0.67N_{Mg}+8N_{P}<1.3 (7)

In addition, the relations of the amounts of Mg and P with the void density after heat treatment were investigated. In the experiment, the Cu—Mg—P alloy thin films were deposited and were subjected to photolithography and wet etching with a mixed acid etchant to thereby fabricate a pattern of interconnections having a line width of 10 μm, followed by vacuum heat treatment at 300° C. for 30 minutes. The voids fabricated in the pattern of interconnections having a line width of 10 μm were counted to determine the void density. A sample thin film having a void density at a practically acceptable level, 1.0×10¹⁰ m⁻² or less, was evaluated as “Passed” (represented by “O” in the drawing) and one having a void density exceeding 1.0×10¹⁰ m⁻² was evaluated as “Failed” (represented by “X” in the drawing).

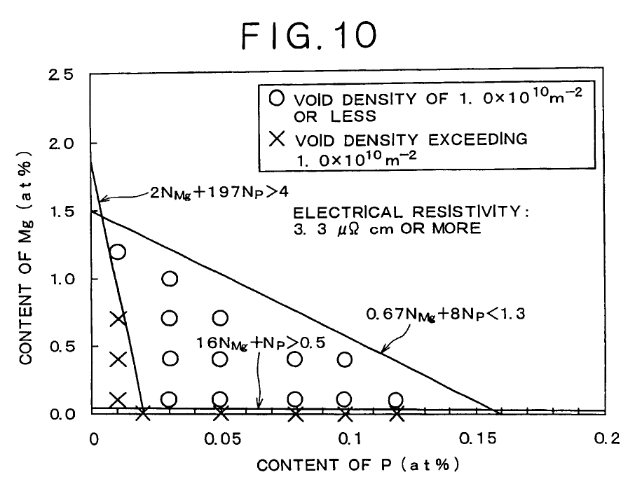

The results are shown in FIG. 10 as the relations of the amounts of Mg and P with the void density after heat treatment in Cu—Mg—P alloy thin films. FIG. 10 verifies that void formation can be inhibited by setting the amounts of Mg and Pin Cu—Mg—P alloy thin film so as to satisfy following conditions (8) and (9):

2N_{Mg}+197N_{P}>4 (8)

16N_{Mg}+N_{P}>0.5 (9)

In addition, the results demonstrate that controlling the amounts of Mg and P in Cu—Mg—P alloy thin films to satisfy following conditions (8) and (9) in combination with Condition (7) necessary for ensuring low electrical resistivities achieves both low electrical resistivities and void inhibition, as is illustrated in FIG. 10. In this case, also, precipitation of Mg₃P₂ at grain boundaries probably contributes to low electrical resistivities and inhibition of voids simultaneously.

0.67N_{Mg}+8N_{P}<1.3 (7)

2N_{Mg}+197N_{P}>4 (8)

16N_{Mg}+N_{P}>0.5 (9)

The film thickness of the Cu alloy thin films according to the present invention is not specifically limited, but it is, for example, generally from about 100 to about 400 nm for interconnection films of flat panel displays mentioned below.

The Cu alloy thin films according to the present invention can be applied to any application not specifically limited, such as interconnection films and/or electrode films of flat panel displays. Specifically suitable applications of the thin films for exhibiting the advantages sufficiently are gate insulator films and source-drain interconnection films in liquid crystal displays.

The term “the balance being substantially Cu” means that the balance other than P, Fe, Co, and Mg comprises Cu and inevitable impurities. As inevitable impurities, the thin films may contain Si, Al, C, O and/or N each in an amount of 100 ppm or less.

The present invention also includes sputtering targets for the deposition of the Cu alloy thin films. When a Cu alloy thin film containing P is deposited, the content of P in the resulting Cu alloy thin film is about 20 percent of the content of P in a sputtering target. Consequently, the sputtering targets for use in the present invention must have a P content about five times that in the target Cu alloy thin film. The compositions of the sputtering targets according to the present invention are specified as follows.

Specifically, the Cu alloy thin film containing Fe and P with the balance being substantially Cu may be deposited by using a Cu alloy sputtering target containing Fe and P with the balance being substantially Cu, in which the contents of Fe and P satisfy all following condition (10) to (12) and the content of P is about five times that in the Cu alloy thin film to be deposited:

1.4N_{Fe}+1.6N_{P}′<1.3 (10)

N_{Fe}+9.6N_{P}′>1.0 (11)

12N_{Fe}+0.2N_{P}′>0.5 (12)

wherein N_{Fe} represents the content of Fe (atomic percent); and N_{P}′ represents the content of P (atomic percent).

The Cu alloy thin film containing Co and P with the balance being substantially Cu may be deposited by using a Cu alloy sputtering target containing Co and P with the balance being substantially Cu, in which the contents of Co and P satisfy all following condition (13) to (15) and the content of P is about five times that in the Cu alloy thin film to be deposited:

1.3N_{Co}+1.6N_{P}′<1.3 (13)

N_{Co}+14.6N_{P}′>1.5 (14)

12N_{Co}+0.2N_{P}′>0.5 (15)

wherein N_{Co} represents the content of Co (atomic percent); and N_{P}′ represents the content of P (atomic percent).

The Cu alloy thin film containing Mg and P with the balance being substantially Cu may be deposited by using a Cu alloy sputtering target containing Mg and P with the balance being substantially Cu, in which the contents of Mg and P satisfy all following condition (16) to (18) and the content of P is about five times that in the Cu alloy thin film to be deposited:

0.67N_{Mg}+1.6N_{P}′<1.3 (16)

2N_{Mg}+39.4 N_{P}′>4 (17)

16N_{Mg}+0.2N_{P}′>0.5 (18)

wherein N_{Mg} represents the content of Mg (atomic percent); and N_{P}′ represents the content of P (atomic percent).

The present invention will be illustrated in further detail with reference to several experimental examples below which by no means limit the scope of the present invention. Any modification of such examples without deviating the scope of the present invention is within the technical range of the present invention.

### EXAMPLE 1

A sputtering target comprising a Cu alloy containing 0.28 atomic percent of Fe and 0.25 atomic percent of P with the balance being Cu and inevitable impurities was prepared by vacuum melting process. Using the sputtering target, a Cu—Fe—P alloy thin film having a thickness of 300 nm was deposited on a glass substrate (#1737 glass available from Corning Inc.) having a diameter of 50.8 mm and a thickness of 0.7 mm by DC magnetron sputtering. The composition of the Cu—Fe—P alloy thin film was analyzed by inductively coupled plasma (ICP) atomic emission spectrometry to find that the content of Fe is 0.28 atomic percent and that the content of P is 0.05 atomic percent. Upon film deposition, about 80% of P was not probably yielded due to its high vapor pressure.

Next, a positive-type photoresist (thickness of 1 μm) was patterned on the Cu-0.28 atomic percent Fe-0.05 atomic percent P alloy thin film, was etched with a mixed acid etchant, and the photoresist was removed with a photoresist remover. The pattern of interconnections having a minimum line width of 10 μm was observed to determine whether or not there was grain boundary delamination and/or hillocks (abnormal protrusions) As a result, neither grain boundary delamination nor hillocks were observed. In addition, the electrical resistivity of the sample was determined by calculation based on the current-voltage properties of the pattern of interconnections.

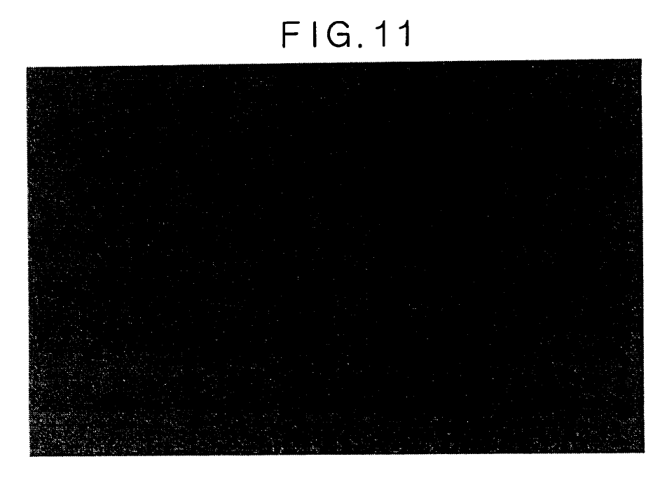

The electrical resistivity of the sample was again determined after heating the sample at 300° C. for 30 minutes in a vacuum heat treatment furnace to find to be 2.73 μΩ·cm. The surface of the sample was observed in detail by SEM, and the result is shown in FIG. 11. The sample thin film shows neither grain boundary delamination nor hillocks and has a void density of 4.5×10⁹ m⁻², at a practically acceptable level of 1.0×10¹⁰ m⁻² or less, even after the heat treatment.

### EXAMPLE 2

A sputtering target comprising a Cu alloy containing 0.35 atomic percent of Co and 0.25 atomic percent of P with the balance being Cu and inevitable impurities was prepared by vacuum melting process. Using the sputtering target, a Cu—Co—P alloy thin film having a thickness of 300 nm was deposited on a glass substrate (#1737 glass available from Corning Inc.) having a diameter of 50.8 mm and a thickness of 0.7 mm by DC magnetron sputtering. The composition of the Cu—Co—P alloy thin film was analyzed By inductively coupled plasma (ICP) atomic emission spectrometry to find that the content of Co is 0.35 atomic percent and that the content of P is 0.05 atomic percent. Upon film deposition, about 80% of P was not probably yielded due to its high vapor pressure as in Example 1.

Next, a positive-type photoresist (thickness of 1 μm) was patterned on the Cu-0.35 atomic percent Co-0.05 atomic percent P alloy thin film, was etched with a mixed acid etchant, and the photoresist was removed with a photoresist remover. The pattern of interconnections having a minimum line width of 10 μm was observed to determine whether or not there was grain boundary delamination and/or hillocks (abnormal protrusions). As a result, neither grain boundary delamination nor hillocks were observed. In addition, the electrical resistivity of the sample was determined by calculation based on the current-voltage properties of the pattern of interconnections.

The electrical resistivity of the sample was again determined after heating the sample at 300° C. for 30 minutes in a vacuum heat treatment furnace to find to be 2.57 μΩ·cm. The surface of the sample was observed in detail by SEM. The sample thin film shows neither grain boundary delamination nor hillocks and has a void density of 5.6×10⁹ m⁻², at a practically acceptable level of 1.0×10¹⁰ m⁻² or less, even after the heat treatment.

### EXAMPLE 3

A sputtering target comprising a Cu alloy containing 0.5 atomic percent of Mg and 0.25 atomic percent of P with the balance being Cu and inevitable impurities was prepared by vacuum melting process. Using the sputtering target, a Cu—Mg—P alloy thin film having a thickness of 300 nm was deposited on a glass substrate (#1737 glass available from Corning Inc.) having a diameter of 50.8 mm and a thickness of 0.7 mm by DC magnetron sputtering. The composition of the Cu—Mg—P alloy thin film was analyzed By inductively coupled plasma (ICP) atomic emission spectrometry to find that the Mg content is 0.5 atomic percent and that the content of P is 0.05 atomic percent. Upon film deposition, about 80% of P was not probably yielded due to its high vapor pressure, as in Examples 1 and 2.

Next, a positive-type photoresist (thickness of 1 μm) was patterned on the Cu-0.5 atomic percent Mg-0.05 atomic percent P alloy thin film, was etched with a mixed acid etchant, and the photoresist was removed with a photoresist remover. The pattern of interconnections having a minimum line width of 10 μm was observed to determine whether or not there was grain boundary delamination and/or hillocks (abnormal protrusions). As a result, neither grain boundary delamination nor hillocks were observed. In addition, the electrical resistivity of the sample was determined by calculation based on the current-voltage properties of the pattern of interconnections.

The electrical resistivity of the sample was again determined after heating the sample at 300° C. for 30 minutes in a vacuum heat treatment furnace to find to be 2.77 μΩ·cm. The surface of the sample was observed in detail by SEM. The sample thin film shows neither grain boundary delamination nor hillocks and has a void density of 5.0×10⁹ m⁻², at a practically acceptable level of 1.0×10¹⁰ m⁻² less, even after the heat treatment.

While the present invention has been described with reference to what are presently considered to be the preferred embodiments, it is to be understood that the invention is not limited to the disclosed embodiments. On the contrary, the invention is intended to cover various modifications and equivalent arrangements included within the spirit and scope of the appended claims. The scope of the following claims is to be accorded the broadest interpretation so as to encompass all such modifications and equivalent structures and functions.

1-9. (canceled)

10: A flat panel display having at least one of interconnection films and electrode films each comprising a Cu alloy thin film comprising Fe and P with the balance being substantially Cu,
wherein the contents of Fe and P satisfy all the following conditions (1) to (3):
1.4N_{Fe}+8N_{P}<1.3 (1)
N_{Fe}+48N_{P}>1.0 (2)
12N_{Fe}+N_{P}>0.5 (3)
wherein N_{Fe} represents the content of Fe (atomic percent); and N_{P} represents the content of P (atomic percent).

11: A flat panel display having at least one of interconnection films and electrode films each comprising a Cu alloy thin film comprising Co and P with the balance being substantially Cu,
wherein the contents of Co and P satisfy all the following conditions (4) to (6):
1.3N_{Co}+8N_{P}<1.3 (4)
N_{Co}+73N_{P}>1.5 (5)
12N_{Co}+N_{P}>0.5 (6)
wherein N_{Co} represents the content of Co (atomic percent), and N_{P} represents the content of P (atomic percent).

12: A flat panel display having at least one of interconnection films and electrode films each comprising a Cu alloy thin film comprising Mg and P with the balance being substantially Cu,
wherein the contents of Mg and P satisfy all the following conditions (7) to (9):
0.67N_{Mg}+8N_{P}<1.3 (7)
2N_{Mg}+197N_{P}>4 (8)
16N_{Mg}+N_{P}>0.5 (9)
wherein N_{Mg} represents the content of Mg (atomic percent); and N_{P} represents the content of P (atomic percent).

13: The flat panel display according to claim 10, wherein in the Cu alloy thin film Fe₂P is precipitated at grain boundaries of Cu.

14: The flat panel display according to claim 11, wherein in the Cu alloy thin film Co₂P is precipitated at grain boundaries of Cu.

15: The flat panel display according to claim 12, wherein in the Cu alloy thin film Mg₃P₂ is precipitated at grain boundaries of Cu.

16: The flat panel display according to claim 10, wherein the void density of the Cu alloy thin film is 1.0×10¹⁰ m⁻² or less.

17: The flat panel display according to claim 11, wherein the void density of the Cu alloy thin film is 1.0×10¹⁰ m⁻² or less.

18: The flat panel display according to claim 12, wherein the void density of the Cu alloy thin film is 1.0×10¹⁰ m⁻² or less.

19: A method of producing a thin film, the method comprising sputtering a Cu alloy thin film from a sputtering target, wherein
the Cu alloy thin film comprises Fe and P with the balance being substantially Cu, wherein the contents of Fe and P satisfy all the following conditions (1) to (3):
1.4N_{Fe}+8N_{P}<1.3 (1)
N_{Fe}+48N_{P}>1.0 (2)
12N_{Fe}+N_{P}>0.5 (3)
wherein N_{Fe} represents the content of Fe (atomic percent); and N_{P} represents the content of P (atomic percent).

20: A method of producing a thin film, the method comprising sputtering a Cu alloy thin film from a sputtering target, wherein the Cu alloy thin film comprises Co and P with the balance being substantially Cu,
wherein the contents of Co and P satisfy all the following conditions (4) to (6):
1.3N_{Co}+8N_{P}<1.3 (4)
N_{Co}+73N_{P}>1.5 (5)
12N_{Co}+N_{P}>0.5 (6)
wherein N_{Co} represents the content of Co (atomic percent); and N_{P} represents the content of P (atomic percent).

21: A method of producing a thin film, the method comprising sputtering a Cu alloy thin film from a sputtering target, wherein the Cu alloy thin film comprises Mg and P with the balance being substantially Cu,
wherein the contents of Mg and P satisfy all the following conditions (7) to (9):
0.67N_{Mg}+8N_{P}<1.3 (7)
2N_{Mg}+197N_{P}>4 (8)
16N_{Mg}+N_{P}>0.5 (9)
wherein N_{Mg} represents the content of Mg (atomic percent); and N_{P} represents the content of P (atomic percent).
